(19) United States
(12) Patent Application Publication
(10) Pub. No.: US 2019/0393184 A1
(43) Pub. Date: Dec. 26, 2019

(54) POWER MODULE AND POWER CONVERSION APPARATUS

(71) Applicant: Mitsubishi Electric Corporation, Tokyo (JP)

(72) Inventors: Satoshi KONDO, Tokyo (JP); Junji FUJINO, Tokyo (JP); Chika MATSUI, Tokyo (JP)

(73) Assignee: Mitsubishi Electric Corporation, Tokyo (JP)

(21) Appl. No.: 16/412,259

(22) Filed: May 14, 2019

(30) Foreign Application Priority Data
Jun. 26, 2018 (JP) 2018-120495

(51) Int. Cl. H01L 23/00; H01L 25/07; H01L 23/498

(52) U.S. Cl. CPC H01L 24/49; H01L 25/072; H01L 23/49861; H01L 2224/49052; H01L 2924/1425; H01L 2924/30107; H01L 2224/4903; H01L 2224/49097

(57) ABSTRACT

A semiconductor element, a substrate on which the semiconductor element is mounted, a connecting portion formed constituted by an arrangement of a plurality of wirings, a casing in which the substrate is disposed on a side of a bottom surface thereof and the semiconductor element and the connecting portion are accommodated therein, and an insulating sealing material filled in the casing, are provided. The plurality of wirings constituting the connecting portion are aligned in a loop shape in a same direction, and each height thereof is arranged such that each of the wiring has a height which is gradually increased one after another toward one direction in the arrangement.

### BACKGROUND OF THE INVENTION

### Field of the Invention

The present invention relates to a power module, and more particularly to a power module in which formation of voids in an insulating sealing material filled in a case is suppressed.

### Description of the Background Art

In a general power module, a circuit is formed by electrically connecting a semiconductor element and a circuit pattern on an insulating substrate with a metal wiring or the like. Along with the increase in density and reliability in the power module, the number of metal wirings connected to the semiconductor element tends to increase, and the arrangement density of the metal wiring has increased. Therefore, as disclosed in, for example, FIG. 9A of the Japanese Unexamined Patent Application Publication (Translation of PCT Application) No. 2007-502544, there are an increasing number of power modules adopting stepped bonding in which bonding is carried out by gradually shifting the bonding position.

However, when the number of metal wirings in the power module is increased due to diversification of the rating of power module and a large current, the wiring interval narrows, and air bubbles contained in the insulating sealing material are less likely to be released from the gaps of the metal wirings, the bubbles are accumulated below the metal wirings, and ultimately, the bubbles remain under the metal wirings as voids.

### SUMMARY

A power module includes a semiconductor element, a substrate on which the semiconductor element is mounted, a connecting portion formed constituted by an arrangement of a plurality of wirings, a casing in which the substrate is disposed on a side of a bottom surface thereof and the semiconductor element and the connecting portion are accommodated therein; and an insulating sealing material filled in the casing, the plurality of wirings constituting the connecting portion are aligned in a loop shape in a same direction, and each height thereof is arranged such that each of the wiring has a height which is gradually increased one after another toward one direction in the arrangement.

Each wiring height of a plurality of wirings is arranged such that each of the wiring has a height which is gradually increased one after another toward one direction in the arrangement, therefore, bubbles contained in the insulating sealing material under the metal wirings readily escape from under the metal wirings, this suppresses voids from being formed under metal wirings.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a power module of Embodiment 1 according to the present invention;

FIG. 2 is a partial plan view illustrating the power module of Embodiment 1 according to the present invention as viewed from above;

FIG. 3 is a plan view illustrating an example of a deaeration structure at a connection part in the power module of Embodiment 1 according to the present invention;

FIG. 4 is a cross-sectional view illustrating Example 1 of the deaeration structure at the connection part in the power module of Embodiment 1 according to the present invention;

FIG. 5 is a schematic diagram illustrating a mechanism of deaeration in the deaeration structure;

FIG. 6 is a plan view illustrating Example 2 of the deaeration structure at the connection part in the power module of Embodiment 1 according to the present invention;

FIG. 7 is a cross-sectional view illustrating Example 2 of the deaeration structure at the connection part in the power module of Embodiment 1 according to the present invention;

FIG. 8 is a plan view illustrating Example 3 of the deaeration structure at the connection part in the power module of Embodiment 1 according to the present invention;

FIG. 9 is a cross-sectional view illustrating Example 3 of the deaeration structure at the connection part in the power module of Embodiment 1 according to the present invention;

FIG. 10 is a cross-sectional view illustrating Example 3 of the deaeration structure at the connection part in the power module of Embodiment 1 according to the present invention;

FIG. 11 is a plan view illustrating Example 4 of the deaeration structure at the connection part in the power module of Embodiment 1 according to the present invention;

FIG. 12 is a cross-sectional view illustrating Example 4 of the deaeration structure at the connection part in the power module of Embodiment 1 according to the present invention;

FIG. 13 is a plan view illustrating Example 5 of the deaeration structure at the connection part in the power module of Embodiment 1 according to the present invention;

FIG. 14 is a plan view illustrating Example 5 of the deaeration structure at the connection part in the power module of Embodiment 1 according to the present invention;

FIG. 15 is a cross-sectional view illustrating Example 5 of the deaeration structure at the connection part in the power module of Embodiment 1 according to the present invention;

FIG. 16 is a plan view illustrating Example 6 of the deaeration structure at the connection part in the power module of Embodiment 1 according to the present invention;

FIG. 17 is a cross-sectional view illustrating Example 6 of the deaeration structure at the connection part in the power module of Embodiment 1 according to the present invention;

FIG. 18 is a plan view illustrating an application example of the deaeration structure at the connection part in the power module of Embodiment 1 according to the present invention to another portion;

FIG. 19 is a cross-sectional view illustrating an application example of the deaeration structure at the connection part in the power module of Embodiment 1 according to the present invention to another portion;

FIG. 20 is a plan view illustrating an application example of the deaeration structure at the connection part in the power module of Embodiment 1 according to the present invention to another portion;

FIG. 21 is a cross-sectional view illustrating an application example of the deaeration structure at the connection part in the power module of Embodiment 1 according to the present invention to another portion; and

FIG. 22 is a block diagram illustrating a configuration of a power conversion apparatus according to Embodiment 2 of the present invention.

### DESCRIPTION OF THE PREFERRED EMBODIMENTS

### Embodiment 1

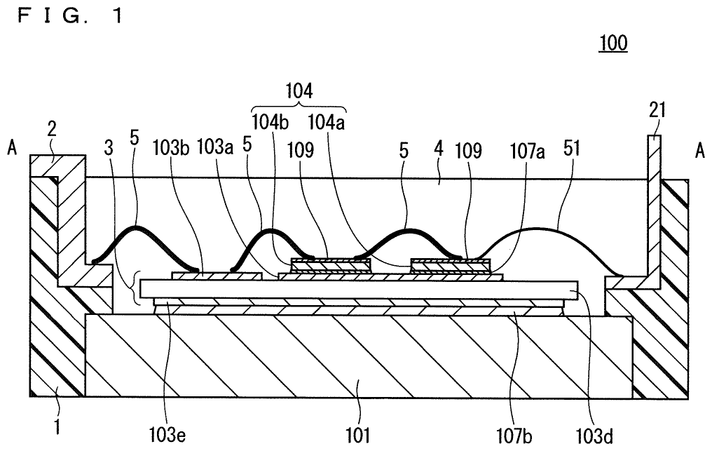

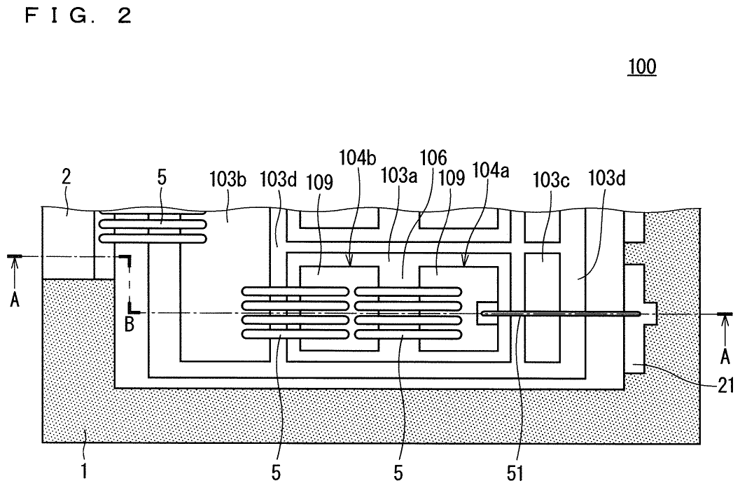

FIG. 1 is a cross-sectional view illustrating a power module of Embodiment 1 according to the present invention. And FIG. 2 is a partial plan view of a power module 100 as viewed from above, and sealing resin and the like are omitted. It should be noted that, the section in the direction of the arrows in the line A-B-A in FIG. 2 is the cross section in FIG. 1.

As shown in FIG. 1, in the power module 100, an insulating substrate 3 is bonded to the upper surface of the base plate 101 by solder (solder under the substrate) 107b, and a semiconductor element 104 including a switching element 104a and a freewheel diode 104b is bonded to the upper surface of the insulating substrate 3 (substrate) by a solder 107a. The base plate 101 is accommodated in an opening portion on the bottom surface side of a casing 1 of which the upper surface side and the bottom surface side are openings, and the base plate 101 having the same shape and the same area as the opening portion on the bottom surface side constitutes the bottom surface of the casing 2.

The insulating substrate 3 is provided with an upper conductor pattern 103a on an upper surface of an insulating material 103d and a lower and a lower conductor patter 103e on a lower surface thereof, and the insulating material 103d is made of, for example, a ceramic material such as resin, Al₂O₃, AlN and Si₃N₄. Or, instead of the insulating substrate 3, a lead frame in which a circuit pattern is patterned may be used.

For example, an Insulated Gate Bipolar Transistor (IGBT) is used as the switching element 104a of the semiconductor element 104. When silicon carbide (SiC)-Metal Oxide Semiconductor Field Effect Transistor (MOSFET) is used as the switching element 104a, SiC-Shottky Barrier Diode (SBD) can also be used as the freewheel diode 104b. A MOSFET made of wide gap semiconductor materials such as SiC, Ga₂O₃, and GaN is high in breakdown voltage and high in allowable current density; therefore, such a MOSFET ensures downsizing compared to a MOSFET made of a silicon semiconductor material, and downsizing of the power module is ensured by incorporating this MOSFET.

The switching element 104a and the freewheel diode 104b are bonded to the upper conductor pattern 103a of the insulating substrate 3 by the solder 107a, a bonding material containing sinterable Ag (silver) or Cu (copper) particles may be used. By using a sinterable bonding material, the life of the bonding portion can be improved as compared with the case of solder bonding. In the case of using a semiconductor device (SiC semiconductor device) using SiC which enables operation at a high temperature, improvement of the life of the bonding portion by using the sinterable material is beneficial in effective use of the characteristics of the SiC semiconductor device.

A main electrode terminal 2 through which a main current flows is provided on the side surface of the casing 1. The main electrode terminal 2 extends from the side surface of the casing 1 to the upper surface of the casing 1, and is exposed to the outside on the upper surface of the casing 1. And, a control terminal 21 is provided on the side surface of the casing 1 on the side where the main electrode terminal 2 is provided, the control terminal 21 extends from the side surface of the casing 1 to the upper surface of the casing 1, and is exposed to the outside on the upper surface of the casing 1.

In the casing 1, the upper electrodes 109 of the switching element 104a and the diode 104b, the upper electrode 109 and the upper conductor pattern 103b of the diode 104b, the upper conductor pattern 103b and the main electrode terminal 2 are connected by a plurality of metal wirings 5. Also, a control electrode (not shown) of the switching element 104a is connected to the control terminal 21 via a metal wiring 1. It should be noted that, hereinafter, the arrangement of a plurality of metal wirings 5 connecting the members and members is referred to as a connecting portion.

The base plate 101 is accommodated in the casing 1, and the casing 1 and the base plate 101 are bonded to each other with a resin adhesive or the like, so that the casing 1 has a bottom and no cover on top. A sealing material 4 such as epoxy resin or the like is introduced from an opening portion on the upper surface side of the casing 1; thereby, the base plate 101, the insulating substrate 3, semiconductor element 104, and metal wirings 5 and 51 are resin sealed with the insulating sealing material 4. It should be noted that, a silicone sealant may be used as the insulate sealing material 4.

Here, as the base plate 101, an AlSiC plate or a Cu plate which is a composite material can be used. However, when using the semiconductor element 104, if the insulating substrate 3 has a sufficient insulation property and strength, the bottom of the casing 1 may be constructed therewith without providing the basing plate 101. That is, the lower conductor pattern 103e is provided on the lower surface of the insulating substrate 3, accordingly, a structure in which the lower conductor pattern 103e is exposed as the bottom surface of the casing 1 may be formed.

As described above, as the number of the metal wirings 5 in the power module 100 increases, the arrangement interval narrows, and air bubbles contained in the insulating sealing material 4 are less likely to be released from the gaps of the metal wiring 5.

### Example 1 of Deaeration Structure

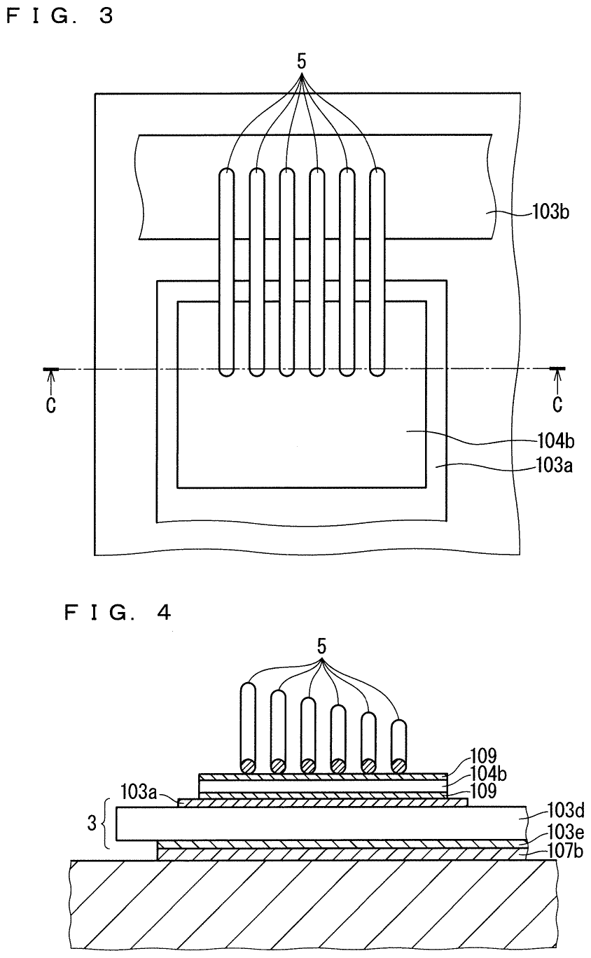

FIGS. 3 and 4 are views illustrating the wiring arrangement of the connection portion having the deaeration structure for moving the bubble under the metal wirings 5 upward when the arrangement interval is narrow. FIG. 3 is a partial plan view of the power module 100 as viewed from above, and FIG. 4 is a cross-sectional view taken along the line C-C in FIG. 3.

FIGS. 3 and 4 illustrate a connecting portion for connecting the diode 104b on the insulating substrate 3 and the upper conductor pattern 103b with a plurality of metal wirings 5 by wire bonding, and as shown in FIG. 3, the arrangement interval of the metal wirings 5 is about the wire width of the metal wiring 5. For example, in the case where the wire width of the metal wiring 5 is about 1 mm and the arrangement interval is 1 mm or narrower, and when the casing 1 is filled with the insulating sealing material 4 and the diameter of the bubbles in the insulating sealing material 4 is 1 mm to 3 mm, the bubbles do not escape from between the metal wirings 4 and are accumulated in the metal wirings 5. The accumulated bubbles may gather together and merged to form bubbles having a larger diameter.

However, as illustrated in FIG. 4, a plurality of metal wirings 5 are arranged such that the metal wirings are aligned in a loop shape in the same direction. The height of the metal wirings 5 are not equal, but are arranged such that each metal wiring 5 has a wiring height which is gradually increased or decreased one after another toward one direction in the arrangement. In FIG. 4, the wiring height is higher toward the left side in the drawing. A structure in which the metal wirings 5 are arranged so that the wiring heights change in this manner is defined as a deaeration structure.

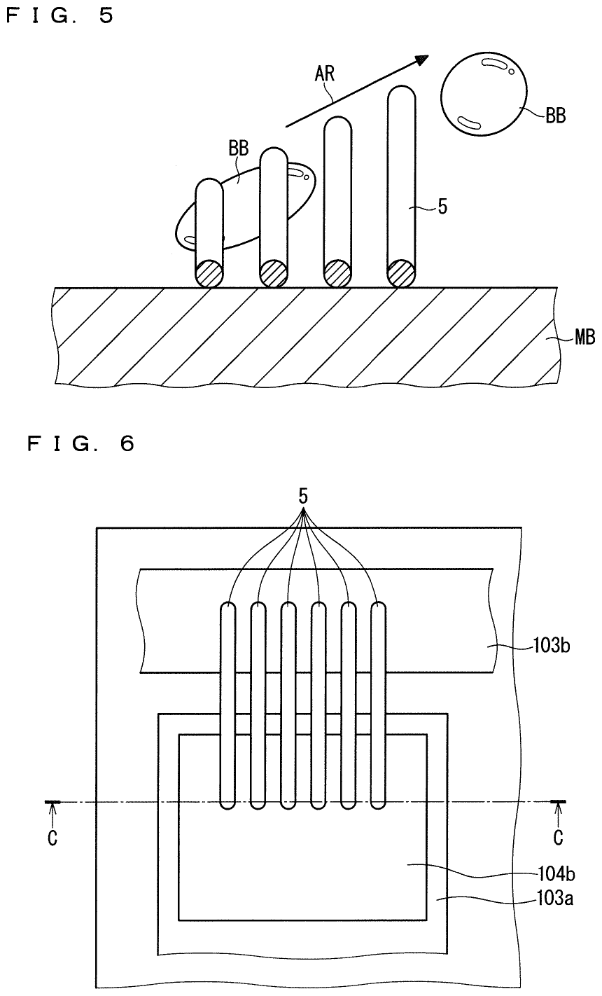

Here, the mechanism of deaeration by the deaeration structure will be described with reference to FIG. 5. In FIG. 5, the deaeration structure in which a plurality of metal wirings 5 are arranged such that the metal wirings are aligned in a loop shape in the same direction, and the wiring height is higher toward the right side in the drawing. A plurality of metal wirings 5 are bonded onto a conductor MB by wire bonding, and bubble BB is present between the plurality of looped metal wires 5 and the conductor MB. The size of the bubble BB is larger than the arrangement interval of the metal wires 5; therefore, the bubble BB cannot pass through between the metal wirings 5. Note that, the plurality of metal wirings 5 including the conductors MB are covered with the insulating sealing material and the bubble BB is present in the insulating sealing material, however, for convenience, the insulating sealing material is not shown.

As illustrated in FIG. 5, the bubble BB initially located on the side of the metal wiring 5 with a low wiring height moves to the side of the metal wiring 5 with a high wiring height with time as indicated by the arrow AR, and eventually escapes from below the metal wirings 5. This is because the bubble BB moves from a low position to a high position due to the difference in specific gravity of the insulating sealing material, for example, 1.9 in the case of epoxy resin and 1 in the case of air, which is specific gravity of the bubble BB. The bubble BB that has escaped from under the metal wirings 5 moves upward in a liquid state before curing of the insulating sealing material and the viscosity of the insulating sealing material temporarily decreases at the time of thermal curing, this causes the bubble BB to readily move upward. For this reason, bubbles in the insulating sealing material gather on the upper surface of the insulating sealing material 4 filled in the casing 1 and are discharged (deaerated) from the insulating sealing material. Thereby, bubbles in the insulating sealing material can be reduced. In the related art, deaeration in which bubbles below the metal wirings 5 are removed has been difficult, however, the above described deaeration structure allows the deaeration in which the bubbles below the metal wirings 5 are removed to be readily performed. Therefore, prevention of a bubble below the metal wirings 5 from being remained, as a void, in the cured insulating sealing material is ensured, and the insulating property of the power module 100 is secured.

### Example 2 of Deaeration Structure

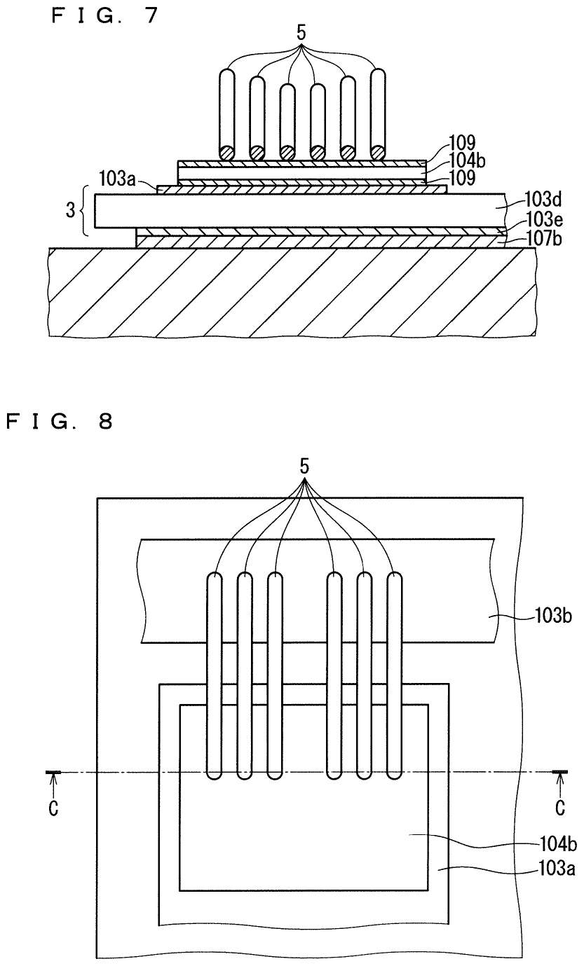

FIGS. 6 and 7 are views illustrating the wiring arrangement having the deaeration structure for moving the bubble under the metal wirings 5 upward when the arrangement interval is narrow. FIG. 6 is a partial plan view of the power module 100 as viewed from above, and FIG. 7 is a cross-sectional view taken along the line C-C in FIG. 6. Note that, arrangement positions of the metal wirings 5 and an arrangement interval and so forth are the same as those in FIGS. 3 and 4.

In the deaeration structure illustrated in FIG. 6, the wiring height of each of the plurality of metal wirings 5 is such that the wiring height in the center portion of the wiring arrangement is the lowest and the wiring heights are higher as the wiring height toward in the left direction (first direction) and toward in the right direction (second direction). Therefore, the bubble present below a plurality of looped metal wirings 5 moves toward at least one of right side and left side in the deaeration structure, escapes from below the metal wirings 5, and the deaeration in which the bubble below the metal wirings 5 is removed is ensured.

### Example 3 of Deaeration Structure

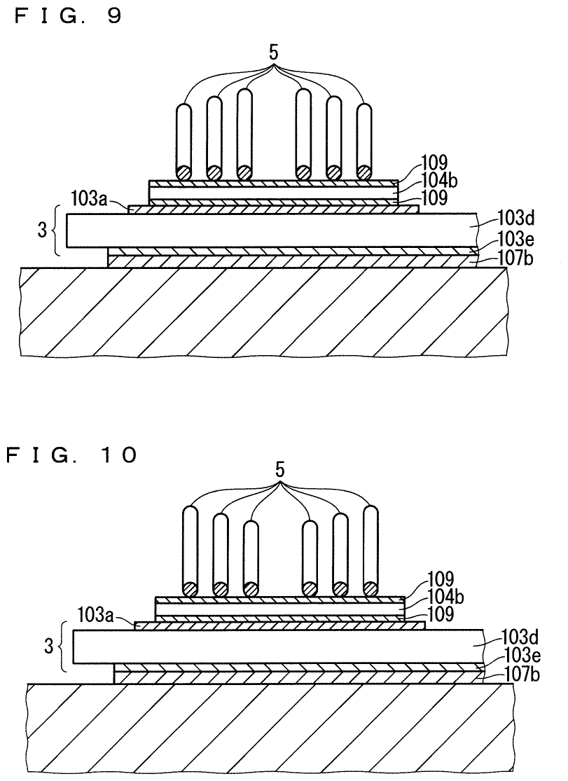

FIGS. 8 and 9 are views illustrating the wiring arrangement having the deaeration structure for moving the bubble under the metal wirings 5 upward when the arrangement interval is narrow. FIG. 8 is a partial plan view of the power module 100 as viewed from above, and FIG. 9 is a cross-sectional view taken along the line C-C in FIG. 8. Note that, arrangement positions of the metal wirings 5 and an arrangement interval are the same as those in FIGS. 3 and 4.

In the deaeration structure illustrated in FIG. 9, the arrangement interval in the center portion of the wiring arrangement is wider than the rest of the portions, and the wiring heights are lower as the wiring height toward in the left direction (first direction) and toward in the right direction (second direction) in the drawing.

Therefore, the bubble present below a plurality of looped metal wirings 5 moves from at least one of right side and left side toward the center portion of the deaeration structure, escapes from below the metal wirings 5, and the deaeration in which the bubble below the metal wirings 5 is removed is ensured.

It should be noted that, the gap in the center portion is set in the range from 1 to 3 mm taking the bubble being 1 to 3 mm in diameter into consideration.

In addition, in the case where the arrangement interval is allowed to be made wider in the center portion than that in other portions of the wiring arrangement, in contrast to the deaeration structure illustrated in FIG. 9, as illustrated in FIG. 10, the deaeration structure may be a structure in which the wiring height of each of the plurality of metal wirings 5 is such that the wiring height in the center portion of the wiring arrangement is the lowest and the wiring heights are higher as the wiring height toward in the left direction (first direction) and toward in the right direction (second direction).

Thereby, the bubble present below a plurality of looped metal wirings 5 moves toward at least one of right side and left side in the deaeration structure, escapes from below the metal wirings 5, and the deaeration in which the bubble below the metal wirings 5 is removed is ensured. It should be noted that, the gap in the center portion the wiring arrangement is wide; therefore, a bubble present below the metal wiring 5 close to the center portion of the wiring arrangement possibly escapes from the center part, and this enhances the effect of deaeration.

### Example 4 of Deaeration Structure

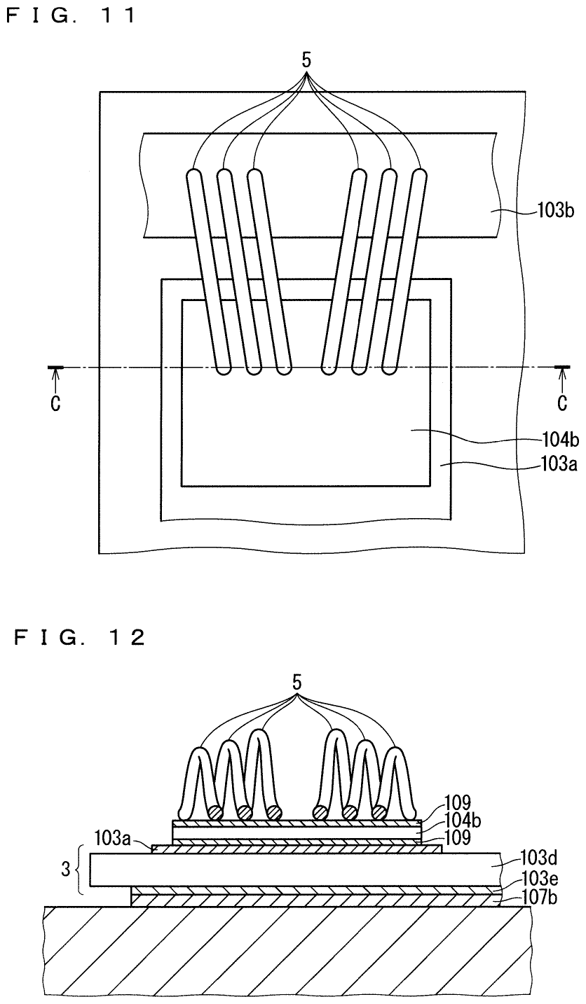

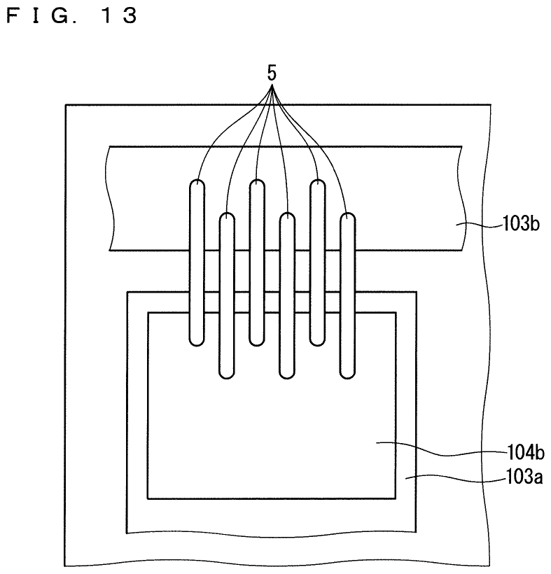

FIGS. 11 and 12 are views illustrating the wiring arrangement having the deaeration structure for moving the bubble under the metal wirings 5 upward when the arrangement interval is narrow. FIG. 11 is a partial plan view of the power module 100 as viewed from above, and FIG. 12 is a cross-sectional view taken along the line C-C in FIG. 11. Note that, arrangement positions of the metal wirings 5 and an arrangement interval are the same as those in FIG. 3.

In the deaeration structure illustrated in FIG. 11, the center portion of the wiring arrangement is wider than the rest of the portions and the metal wirings 5 are arranged so as to be inclined obliquely in the left direction (first direction) and the right direction (second direction) with the central portion as a boundary. Therefore, as illustrated in FIG. 12, the wiring height of each of the plurality of metal wirings 5 is such that is lowered as the wiring height toward in the left direction and the right direction, and the back side (the side of the upper conductor pattern 103b) is wider than the front side (the side of the diode 104b) in the central portion.

Therefore, the bubble present below a plurality of looped metal wirings 5 readily escapes from the center portion of the deaeration structure.

### Example 5 of Deaeration Structure

FIG. 13 is a view illustrating the wiring arrangement having the deaeration structure for moving the bubble under the metal wirings 5 upward when the arrangement interval is narrow, and FIG. 13 is a partial plan view of the power module 100 as viewed from above.

The deaeration structure illustrated in FIG. 13, the positions of bonding of adjacent metal wirings 5 shifted one after another and bonded in a staggered state. By bonding in the staggered state facilitates bonding even in the case where the arrangement interval is even narrower since a space for inserting bonding equipment is secured.

For example, as illustrated in FIG. 4, The height of a plurality of metal wirings 5 are not equal, but are arranged such that each metal wiring 5 has a wiring height which is gradually increased or decreased one after another toward one direction in the arrangement. Therefore, even in the case of bonding in the staggered state, a bubble present below a plurality of loop-shaped metal wirings 5 moves toward the side of the metal wiring 5 with a high wiring height and deaeration is performed.

And, as described above, in the case of the bonding in the staggered state, in which each metal wiring 5 has a wiring height different from one after another, inductances (electric resistance) are to be changed due to the varied wiring lengths. Therefore, the inductances can be unified by having a uniform wiring length, and designing the circuit for the power module 100 can be simplified.

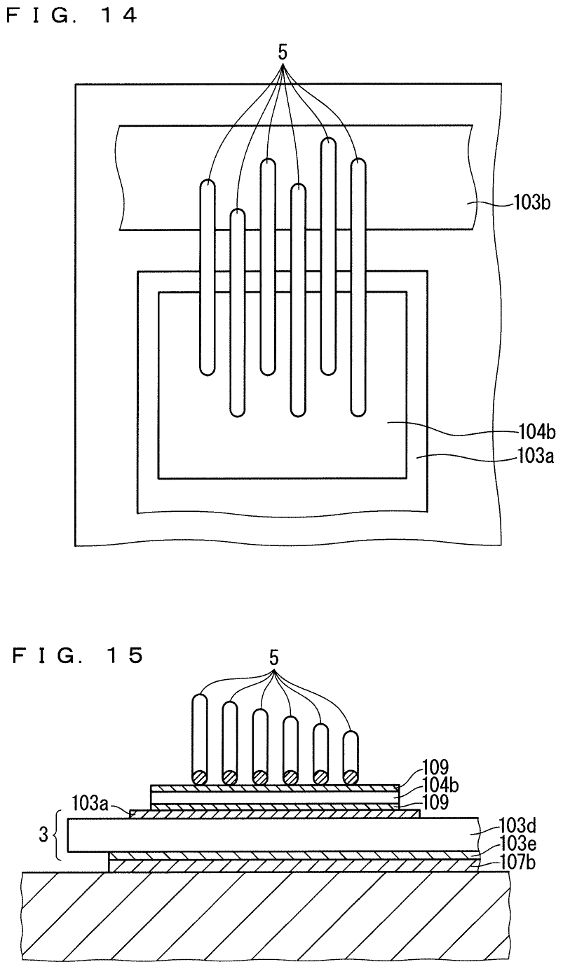

FIG. 14 is a plan view illustrating the deaeration structure in which the wiring lengths are uniform in the case of the bonding in the staggered state, and FIG. 15 is a cross-sectional view corresponding to the FIG. 4.

As illustrated in FIGS. 14 and 15, the length of each of the plurality of metal wirings 5 is set in plan view such that the wiring length of the metal wiring 5 having the lowest wiring height in the plan view is longest and the wiring length in the plan view of the metal wiring 5 having the highest wiring height is the longest. As a result, the full length (actual wiring length) of each of the metal wirings 5 is uniform, so that the inductances can be unified.

Varying the respective wiring lengths in plan view in accordance with the respective wiring heights may be applied to the deaeration structures of Examples 1 to 4, and by unifying the inductances, designing the circuit for the power module 100 can be simplified.

### Example 6 of Deaeration Structure

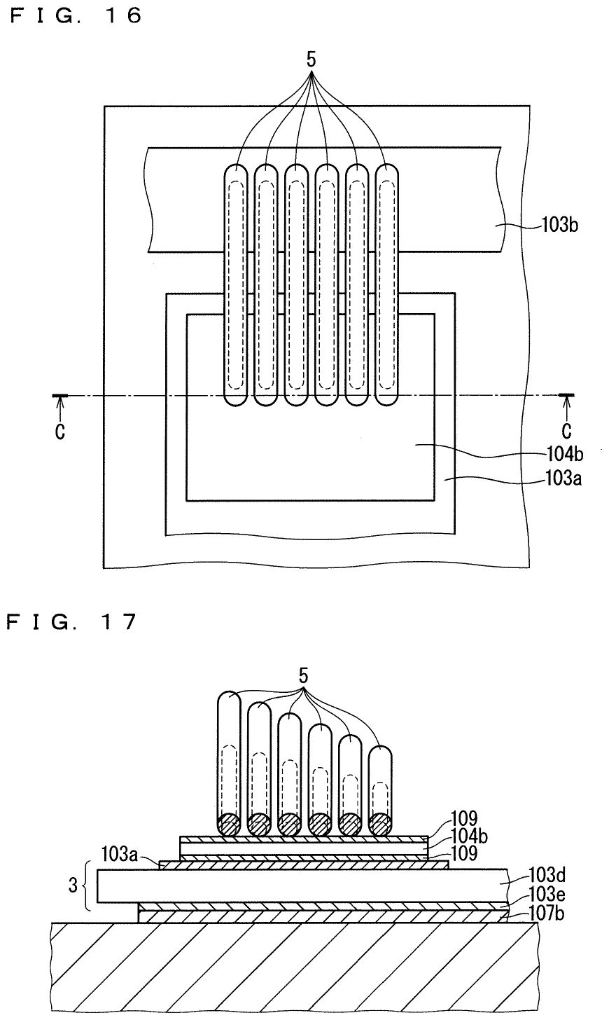

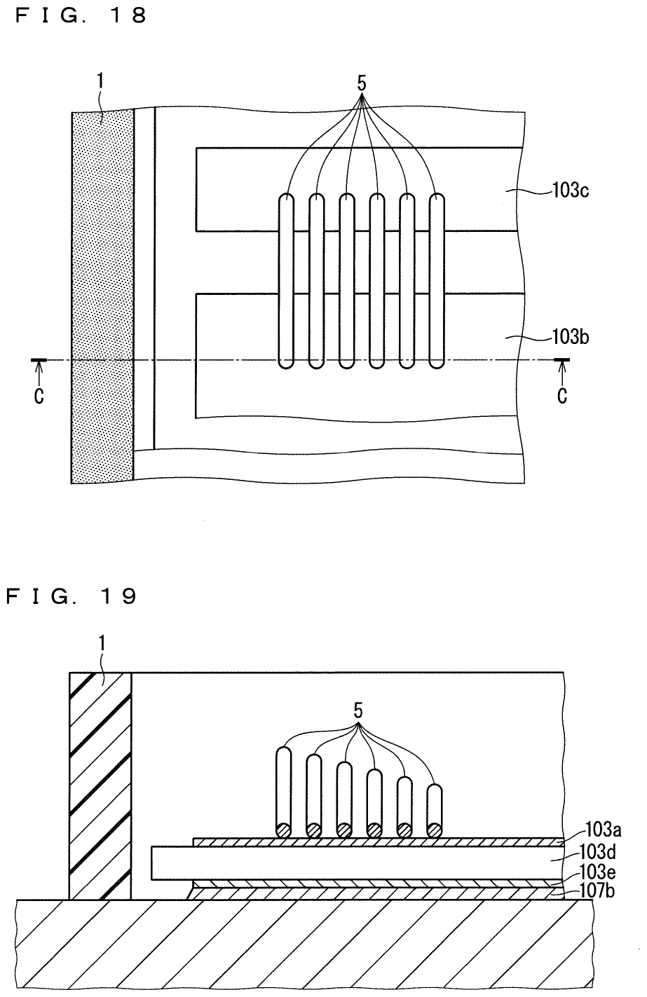

FIGS. 16 and 17 are views illustrating the wiring arrangement having the deaeration structure for moving the bubble under the metal wirings 5 upward when the arrangement interval is narrow. FIG. 16 is a partial plan view of the power module 100 as viewed from above, and FIG. 17 is a cross-sectional view taken along the line C-C in FIG. 16. Note that, arrangement positions of the metal wirings 5 and an arrangement interval are the same as those in FIG. 3. It should be noted that, the upper sides of the metal wirings 5 are illustrated thickly for convenience in FIGS. 16 and 17, and the upper and lower metal wirings 5 actually the same thickness.

FIGS. 16 and 17 illustrate a deaeration structure of double wiring in which the metal wirings 5 are arranged so as to overlap each other vertically in a looping direction. As illustrated in FIG. 17, the height of the metal wirings 5 are arranged such that each metal wiring 5 has a wiring height which is gradually increased or decreased one after another toward one direction in the arrangement. As a result, even in the case of such double wiring, the bubble present below a plurality of looped metal wirings 5 move toward the side of the metal wiring 5 with a high wiring height and the deaeration is ensured. It should be noted that, the deaeration structure is not limited to the above-described double wiring, and the deaeration structure is also applicable to a wiring which is further overlapped such as a triple wiring.

### Applicable Example of Deaeration Structure to Another Portion

In the above described deaeration structure of Examples 1 to 6, although the connecting portion between the diode 104b and the upper conductor pattern 103b has been described, the deaeration structure may be applied to another connecting portion.

FIGS. 18 and 19 illustrate a case to which Example 1 of the deaeration structure is applied, for example, at the connecting portion between the upper conductor pattern 103b and the other upper conductor pattern 103c. FIG. 18 is a partial plan view of the power module 100 as viewed from above, and FIG. 19 is a cross-sectional view taken along the line C-C in FIG. 18. The height of a plurality of metal wirings 5 are arranged such that each metal wiring 5 has a height which is gradually increased or decreased one after another toward one direction in the arrangement. It should be noted that the upper conductor pattern 103c is in a portion not shown in the plan view illustrated in FIG. 2.

As illustrated in FIGS. 18 and 19, by applying the deaeration structure to the case where conductor patterns on the insulating substrate 3 are connected to each other, a bubble present below a plurality of looped metal wirings 5 moves toward the side of the metal wiring 5 with a high wiring height and deaeration is performed.

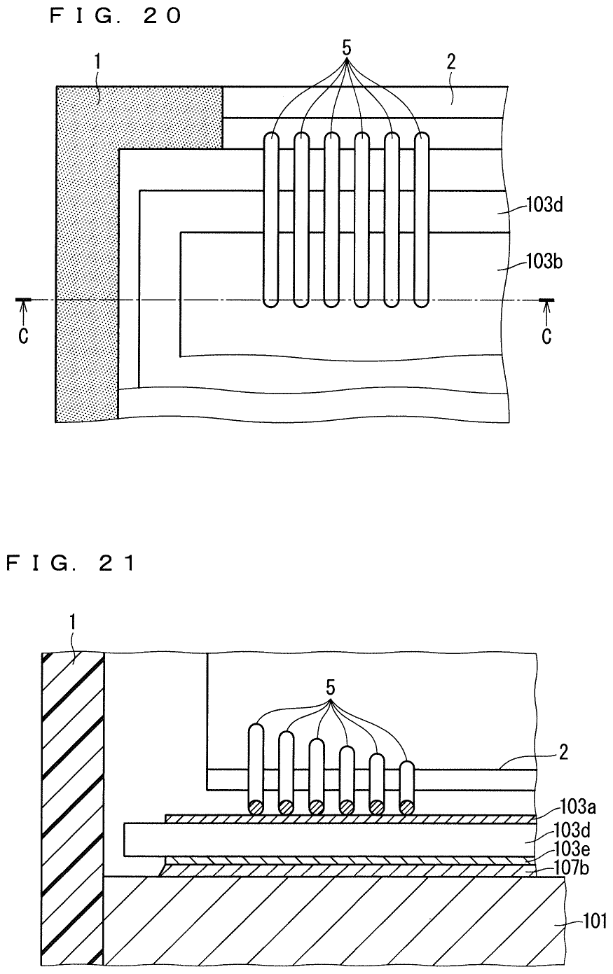

FIGS. 20 and 21 illustrate a case to which Example 1 of the deaeration structure is applied, for example, at the connecting portion between the upper conductor pattern 103b and the main electrode terminal 2. FIG. 20 is a partial plan view of the power module 100 as viewed from above, and FIG. 21 is a cross-sectional view taken along the line C-C in FIG. 20. The height of a plurality of metal wirings 5 are arranged such that each metal wiring 5 has a height which is gradually increased or decreased one after another toward one direction in the arrangement.

As illustrated in FIGS. 20 and 21, by applying the deaeration structure to the case where conductor pattern 3 on the insulating substrate 3 and the main electrode terminal 2 are connected to each other, a bubble present below a plurality of looped metal wirings 5 moves toward the side of the metal wiring 5 with a high wiring height and deaeration is performed.

<Other Structure for Deaeration>

In Embodiment 1 described above, for example, when the arrangement interval of the metal wirings 5 is 1 mm or less and the diameter of a bubble in the insulating sealing material 4 is 1 mm to 3 mm, the bubble does not escape from between the metal wirings 5, however, by setting the interval between the metal wirings 5 larger than the diameter of the bubble, a deaeration structure can be obtained.

However, when the wire width of the metal wiring 5 is about 1 mm, if the wiring interval is set to about 3 mm, an increase in wiring density due to diversification of the rating of power module and a large current is failed to cope with. Therefore, by increasing the wire width of the metal wiring 5 or by using a plate-like ribbon bond, the fusing current per wiring is increased so that the wiring interval is 1 mm or more.

### Embodiment 2

In Embodiment 2, the power module according to the above-described Embodiment 1 is applied to a power conversion apparatus. Hereinafter, the case where Embodiment 1 is applied to a three-phase inverter will be described as Embodiment 2.

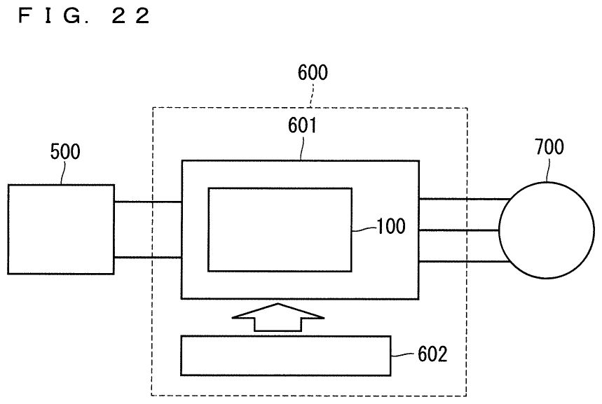

FIG. 22 is a block diagram illustrating a configuration of a power conversion system to which a power conversion apparatus according to Embodiment 2 is applied.

The power conversion system illustrated in FIG. 22 includes a power source 500, a power conversion apparatus 600, and a load 700. The power source 500 is a DC power source and supplies DC power to the power conversion apparatus 600. The power source 500 can be various types, such as a DC system, a solar cell, a storage battery, alternatively, the power source 500 may include a rectifier circuit or an AC/DC converter connected to an AC system. Further, the power source 500 may be constituted by a DC/DC converter that converts DC power output from the DC system into predetermined electric power.

The power conversion apparatus 600 is a three-phase inverter connected to the power source 500 and the load 700, and converts DC power supplied from the power source 500 into AC power then supplies the AC power to the load 700. As illustrated in FIG. 22, the power conversion apparatus 600 includes a main conversion circuit 601 for converting DC power into AC power and outputting the AC power and a control circuit 602 for outputting a control signal for controlling the main conversion circuit 601 to the main conversion circuit 601.

The load 700 is a three-phase motor driven by AC power supplied from the power conversion apparatus 600. It should be noted that, the load 700 is not limited to a specific use, and is a motor mounted in various electric apparatuses, for example, the load 700 is used as a motor for hybrid vehicles, electric vehicles, railway vehicles, elevators, or air conditioning apparatuses.

Hereinafter, details of the power conversion apparatus 600 will be described. The main conversion circuit 601 includes a switching element and a freewheel diode (not illustrated), the switching element converts DC power supplied from the power source 500 into AC power by performing switching and supplies thereof to the load 700. There are various specific circuit configurations of the main conversion circuit 601, and the main conversion circuit 601 according to Embodiment 2 is a two-level three-phase full-bridge circuit which can be composed of six switching elements and six freewheel diodes each of which is connected in reversely parallel to the respective switching elements. The power module 100 according to Embodiment 1 is applied to the power module including the main conversion circuit 601, and a plurality of metal wirings 5 in the power module 100 are disposed using the deaeration structure. In the six switching elements, for each pair of switching elements, an upper arm and a lower arm are formed by connecting the switching elements in series, and each pair of upper arm and lower arm constitutes each phase (U-phase, V-phase, W-phase) of the full bridge circuit. And, an output terminal of each pair of upper arm and lower arm, that is, three output terminals of the main conversion circuit 601 are connected to the load 700.

And, the main conversion circuit 601 includes a driving circuit (not shown) for driving each switching element, and the driving circuit may be built in the power module 100 as described in Embodiment 1, or may have a configuration in which the driving circuit is provided separately from the power module 100.

The driving circuit generates a driving signal for driving each switching element of the main conversion circuit 601 and supplies thereof to a control electrode of the switching element of the main conversion circuit 601. Specifically, in accordance with the control signal from the control circuit 602 which will be described later, the driving circuit outputs the driving signal for turning each switching element to the ON state and the driving signal for turning each switching element to the OFF state to the control electrode of each switching element. When the ON state of the switching element is maintained, the driving signal is a voltage signal (ON signal) equal to or higher than the threshold voltage of the switching element while when the OFF state of the switching element is maintained, the driving signal is a voltage signal (OFF signal) lower than the threshold voltage of the switching element.

The control circuit 602 controls the switching element of the main conversion circuit 601 so that desired power is supplied to the load 700. Specifically, the control circuit 602 calculates the time (ON time) that each switching element of the main conversion circuit 601 should be in the ON state based on the power to be supplied to the load 700. For example, the main conversion circuit 601 can be controlled by PWM control for modulating the ON time of the switching element according to the voltage to be output. Then, a control command (control signal) is output to the driving circuit 602 so that an ON signal is output to the switching elements to be ON state and an OFF signal is output to the switching elements to be OFF state at each point of time. In accordance with the control signal, the driving circuit 602 outputs the ON signal or the OFF signal as the driving signal to the control electrode of each switching element.

By configuring the main conversion circuit 601 with the power module 100 according to Embodiment 1, it is possible to suppress bubbles from remaining as voids below the metal wirings 5 in the cured insulating sealing material. Thereby troubles of the power module secured insulating property and the power conversion device including the power module are avoided in advance and functions thereof are prevented from being damaged.

In Embodiment 2, an example in which the present invention is applied to a two-level three-phase inverter has been described, however, the present invention is not limited to this and can be applied to various power conversion apparatuses. In Embodiment 2, although a two-level power conversion apparatus is applied, however, a three-level or multi-level power conversion apparatus may be applied, and when supplying power to a single-phase load, the present invention is applied to a single-phase inverter may be applied. In the case where power is supplied to a direct current load and so forth, the present invention can also be applied to a DC/DC converter or an AC/DC converter.

In addition, the power conversion apparatus according to Embodiments is applied is not limited to the case where the above-described load is an electric motor, and may be applied to, for example, power source equipment of an electric discharge machine, a laser processing machine, an induction heating cooker or a non-contact power supply system, and further, can also be used as a power conditioner for a photovoltaic power generation system or a power storage system, for example.

The present invention can be appropriately modified or omitted without departing from the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A power module, comprising:
a semiconductor element;
a substrate on which the semiconductor element is mounted;
a connecting portion formed constituted by an arrangement of a plurality of wirings;
a casing in which the substrate is disposed on a side of a bottom surface thereof and the semiconductor element and the connecting portion are accommodated therein; and
an insulating sealing material filled in the casing,
the plurality of wirings constituting the connecting portion being aligned in a loop shape in a same direction, and each height thereof being arranged such that each of the wiring has a height which is gradually increased one after another toward one direction in the arrangement.

2. The power module according to claim 1, wherein
the plurality of wirings of the connecting portion are arranged such that wiring height in a center portion of the arrangement is lowest and the wiring heights are higher as the wiring height toward in a first direction and toward in a second direction.

3. The power module according to claim 1, wherein
the plurality of wirings of the connecting portion are arranged such that an arrangement interval is wider and the wiring height is highest in a center portion than rest portions of the arrangement, and each of the plurality of wirings has a wiring height which is gradually decreased from the center portion toward the first direction and is also gradually decreased toward the second direction which is an opposite direction of the first direction.

4. The power module according to claim 1, wherein
the plurality of wirings of the connecting portion are arranged such that an arrangement interval is wider and the wiring height is lowest in a center portion than rest portions of the arrangement, and each of the plurality of wirings has a wiring height which is gradually increased from the center portion toward the first direction and is also gradually increased toward the second direction which is an opposite direction of the first direction.

5. The power module according to claim 1, wherein
the plurality of wirings of the connecting portion are arranged such that an arrangement interval is wider and the wiring height is highest in a center portion than rest portions of the arrangement, and each of the plurality of wirings has a wiring height which is gradually decreased from the center portion toward the first direction and is also gradually decreased toward the second direction which is an opposite direction of the first direction, and, in plan view, the wirings are arranged so as to be inclined obliquely in the first direction and the second direction with the central portion as a boundary.

6. The power module according to claim 1, wherein
the plurality of wirings of the connecting portion includes double wiring in which the wirings are arranged so as to overlap each other vertically in a looping direction.

7. The power module according to claim 1, wherein
each of the plurality of wirings of the connecting portion is set such that the wiring length having a highest wiring height in plan view is shortest and the wiring length having a lowest wiring height in plan view is longest so as to make a full length of each of the plurality of wirings uniform for unified inductances.

8. The power module according to claim 1, wherein
the connecting portion includes at least a portion electrically connecting the semiconductor element and a main electrode terminal through which a main current of the semiconductor element flows, a portion between the semiconductor elements, and a portion between the conductor patterns.

9. A power conversion apparatus, comprising:
a main conversion circuit including the power module according to claim 1, and configured to convert and output power to be input; and
a control circuit configured to output a control signal for controlling the main conversion circuit to the main conversion circuit.
